(19) United States
(12) Patent Application Publication
(10) Pub. No.: US 2024/0153865 A1
(43) Pub. Date: May 9, 2024

(54) METAL VIA MULTI-LEVELS

(71) Applicant: INTERNATIONAL BUSINESS MACHINES CORPORATION, Armonk, NY (US)

(72) Inventors: Yann Mignot, Singerlands, NY (US); Koichi Motoyama, Clifton Park, NY (US); Hsueh-Chung Chen, Cohoes, NY (US); Chanro Park, Clifton Park, NY (US)

(21) Appl. No.: 17/980,617

(22) Filed: Nov. 4, 2022

(51) Int. Cl. H01L 23/522; H01L 21/768; H01L 23/532

(52) U.S. Cl. CPC H01L 23/5226; H01L 21/76885; H01L 23/5221; H01L 23/53266

(57) ABSTRACT

A semiconductor structure is presented including a first level of interconnect wiring and a second level of interconnect wiring having a bilayer metal arrangement incorporating via elements, the second level of interconnect wiring electrically connected to the first level of interconnect wiring. In one example, the bilayer metal arrangement of the second level of interconnect wiring includes a first row of bilayer metals and a second row of bilayer metals disposed over the first row of bilayer metals. In another example, the bilayer metal arrangement of the second level of interconnect wiring includes a cap dielectric material for isolation from the first row of the bilayer metal. In yet another embodiment, the bilayer metal arrangement of the second level of interconnect wiring includes a metal bridge.

### BACKGROUND

The present invention relates generally to semiconductor devices, and more specifically, to constructing metal via multi-levels.

Semiconductor devices are used in a variety of electronic applications, such as personal computers, cell phones, digital cameras, and other electronic equipment. Semiconductor devices are usually fabricated by sequentially depositing insulating or dielectric layers, conductive layers, and semiconductive layers of material over a semiconductor substrate, and patterning the various material layers using lithography to form circuit components and elements thereon.

The semiconductor industry has experienced rapid growth due to improvements in the integration density of a variety of electronic components (e.g., transistors, diodes, resistors, capacitors, etc.). For the most part, this improvement in integration density has come from shrinking the semiconductor process node. With the increased demands for miniaturization, higher speed, greater bandwidth, lower power consumption, and lower latency, chip layout has become more complicated and difficult to achieve in the production of semiconductor dies.

### SUMMARY

In accordance with an embodiment, a semiconductor structure is provided. The semiconductor structure includes a first level of interconnect wiring and a second level of interconnect wiring having a bilayer metal arrangement incorporating via elements, the second level of interconnect wiring electrically connected to the first level of interconnect wiring.

In accordance with another embodiment, a semiconductor structure is provided. The semiconductor structure includes a first level of interconnect wiring and a second level of interconnect wiring having a bilayer metal arrangement incorporating via elements and a cap dielectric material, the second level of interconnect wiring electrically connected to the first level of interconnect wiring.

In accordance with yet another embodiment, a semiconductor structure is provided. The semiconductor structure includes a first level of interconnect wiring and a second level of interconnect wiring having a bilayer metal arrangement incorporating via elements and a metal bridge, the second level of interconnect wiring electrically connected to the first level of interconnect wiring.

It should be noted that the exemplary embodiments are described with reference to different subject-matters. In particular, some embodiments are described with reference to method type claims whereas other embodiments have been described with reference to apparatus type claims. However, a person skilled in the art will gather from the above and the following description that, unless otherwise notified, in addition to any combination of features belonging to one type of subject-matter, also any combination between features relating to different subject-matters, in particular, between features of the method type claims, and features of the apparatus type claims, is considered as to be described within this document.

These and other features and advantages will become apparent from the following detailed description of illustrative embodiments thereof, which is to be read in connection with the accompanying drawings.

### BRIEF DESCRIPTION OF THE DRAWINGS

The invention will provide details in the following description of preferred embodiments with reference to the following figures wherein:

FIG. 1 is a cross-sectional view of a semiconductor structure including a litho stack over metal layers, in accordance with an embodiment of the present invention;

FIG. 2 is a cross-sectional view of the semiconductor structure of FIG. 1 where litho patterning takes place to form a first set of a plurality of metal trenches, in accordance with an embodiment of the present invention;

FIG. 3 is a cross-sectional view of the semiconductor structure of FIG. 2 where a cut mask is optionally applied to selectively remove metal trench portions, in accordance with an embodiment of the present invention:

FIG. 4 is a cross-sectional view of the semiconductor structure of FIG. 3 where a first dielectric is deposited and planarization takes place to a top surface of the first set of the plurality of metal trenches, in accordance with an embodiment of the present invention;

FIG. 5 is a cross-sectional view of the semiconductor structure of FIG. 3 where spacers are formed, a first dielectric is deposited, and planarization takes place to a top surface of the first set of the plurality of metal trenches, in accordance with another embodiment of the present invention;

FIG. 6 is a cross-sectional view of the semiconductor structure of FIG. 5 where metal layers and another litho stack are formed thereon, in accordance with an embodiment of the present invention;

FIG. 7 is a cross-sectional view of the semiconductor structure of FIG. 6 where the metal layers are etched to a top surface of the first set of the plurality of metal trenches below to expose the first dielectric and to create a second set of a plurality of metal trenches, in accordance with an embodiment of the present invention;

FIG. 8 is a cross-sectional view of the semiconductor structure of FIG. 7 where a second dielectric is deposited and planarization takes place to a top surface of the second set of the plurality of metal trenches, in accordance with an embodiment of the present invention;

FIG. 9 is a cross-sectional view of the semiconductor structure of FIG. 4 where litho patterning takes place over the first set of the plurality of metal trenches, in accordance with another embodiment of the present invention;

FIG. 10 is a cross-sectional view of the semiconductor structure of FIG. 9 where selective etching takes place to expose one or more of the first set of the plurality of metal trenches, in accordance with an embodiment of the present invention;

FIG. 11 is a cross-sectional view of the semiconductor structure of FIG. 10 where a top metal layer of the exposed first metal trenches is selectively removed, in accordance with an embodiment of the present invention;

FIG. 12 is a cross-sectional view of the semiconductor structure of FIG. 11 where a cap dielectric material is deposited and planarization is performed, in accordance with an embodiment of the present invention;

FIG. 13 is a cross-sectional view of the semiconductor structure of FIG. 5 where a cap dielectric material is deposited and planarization is performed (where spacers were formed adjacent the first set of the plurality of metal trenches), in accordance with an embodiment of the present invention;

FIG. 14 is a cross-sectional view of the semiconductor structure of FIGS. 12 and 13 illustrating the cap dielectric material between the M1 layer and the M2V1 layer, in accordance with an embodiment of the present invention:

FIG. 15 is a cross-sectional view of the semiconductor structure of FIG. 5 where litho patterning takes place over the first set of the plurality of metal trenches, and where a single dielectric encompasses the first set of the plurality of metal trenches, in accordance with another embodiment of the present invention;

FIG. 16 is a cross-sectional view of the semiconductor structure of FIG. 15 where selective etching takes place to expose the first set of the plurality of metal trenches, in accordance with an embodiment of the present invention;

FIG. 17 is a cross-sectional view of the semiconductor structure of FIG. 16 where a metal bridge is formed and planarized, in accordance with an embodiment of the present invention;

FIG. 18 is a 3D view and cross-sectional view of a via (V1) connecting an M1 layer to an M2 layer;

FIG. 19 is a 3D view and cross-sectional view of a M2V1 layer connected over an M1 layer composed by a bi-metal as illustrated in FIG. 8, in accordance with an embodiment of the present invention;

FIG. 20 is a 3D view and cross-sectional view of a M2V1 layer connected to an M1 layer and isolated by a cap dielectric material in selected region as illustrated in FIG. 13, in accordance with an embodiment of the present invention; and

FIG. 21 is a 3D view and cross-sectional view of a M2V1 layer connected to an M1 layer by a bridge metal as illustrated in FIG. 17, in accordance with an embodiment of the present invention.

Throughout the drawings, same or similar reference numerals represent the same or similar elements.

### DETAILED DESCRIPTION

Embodiments in accordance with the present invention provide methods and devices for constructing metal via multi-levels. The exemplary semiconductor structures include multi single-level schemes combining trench and via elements. The pattern can be achieved by employing single exposition patterning (SE), self-aligned double patterning (SADP) or self-aligned litho-etch-litho-etch (SALELE) or litho-etch-litho-etch (LELE) with a cut. As a result, there is no need of a specific via mask with a feature like a self-aligned via (SAV) or fully self-aligned via (FSAV). This results in an overlay improvement as a line-over-line configuration is achieved and a reduced footprint as via-to-via distance doesn't exist.

Examples of semiconductor materials that can be used in forming such structures include silicon (Si), germanium (Ge), silicon germanium alloys (SiGe), silicon carbide (SiC), silicon germanium carbide (SiGeC), III-V compound semiconductors and/or II-VI compound semiconductors. III-V compound semiconductors are materials that include at least one element from Group III of the Periodic Table of Elements and at least one element from Group V of the Periodic Table of Elements. II-VI compound semiconductors are materials that include at least one element from Group II of the Periodic Table of Elements and at least one element from Group VI of the Periodic Table of Elements.

It is to be understood that the present invention will be described in terms of a given illustrative architecture; however, other architectures, structures, substrate materials and process features and steps/blocks can be varied within the scope of the present invention. It should be noted that certain features cannot be shown in all figures for the sake of clarity. This is not intended to be interpreted as a limitation of any particular embodiment, or illustration, or scope of the claims.

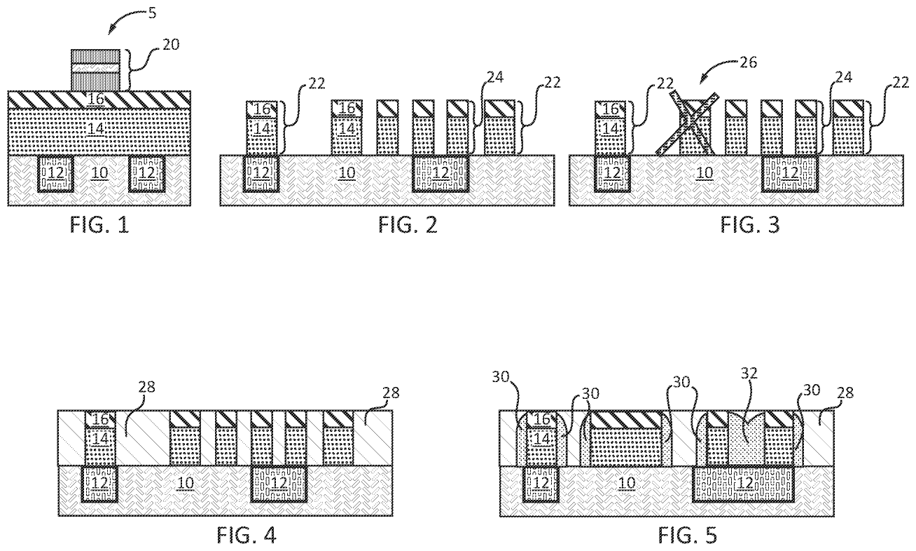

FIG. 1 is a cross-sectional view of a semiconductor structure including a litho stack over metal layers, in accordance with an embodiment of the present invention.

In various example embodiments, structure 5 includes metal lines 12 (M1) formed within a dielectric material 10. In an alternative structure, middle-of-line (MOL) contacts form the metal lines 12 within the dielectric material 10. A bilayer metal is deposited over the metal lines 12. The bilayer metal includes a first metal layer 14 and a second metal layer 16. A litho stack 20 is deposited over the bilayer metal. The first metal layer 14 can be, e.g., ruthenium (Ru). The Ru layer can have a thickness of about 10-50 nm. The second metal layer 16 can be, e.g., titanium nitride (TiN) or tantalum nitride (TaN). The TiN or TaN layer can have a thickness of about 5-10 nm.

The metal lines 12 (M1) represent a first level of interconnect wiring or the last MOL contact level.

Non-limiting examples of suitable conductive materials for the first level of interconnect wiring include a refractory metal liner such as TaN, an adhesion metal liner, such as Co or Ru, and a conductive metal fill, such as Al, W, Cu, Co, Ru, Mo, Ir, etc. The conductive material can further include dopants that are incorporated during or after deposition. The conductive metal can be deposited by a suitable deposition process, for example, CVD, PECVD, PVD, plating, thermal or e-beam evaporation, and sputtering. The only requirement for the first metal layer 14 and the second metal layer 16 is to have enough etch selectivity against each other in the order of greater than 10:1, respectively.

Regarding various dielectrics or dielectric layers discussed herein, the dielectrics can include, but are not limited to, SiN, SiOCN, SiOC, SiC, SiON, SiBCN, SO₂, or ultra-low-k (ULK) materials, such as, for example, porous silicates, carbon doped oxides, silicon dioxides, silicon nitrides, silicon oxynitrides, carbon-doped silicon oxide (SiCOH) and porous variants thereof, silsesquioxanes, siloxanes, or other dielectric materials having, for example, a dielectric constant in the range of about 2 to about 10.

In some embodiments, the dielectrics can be conformally deposited using atomic layer deposition (ALD) or, chemical vapor deposition (CVD). Variations of CVD processes suitable for forming the dielectrics include, but are not limited to, Atmospheric Pressure CVD (APCVD), Low Pressure CVD (LPCVD) and Plasma Enhanced CVD (PECVD), Metal-Organic CVD (MOCVD) and combinations thereof can also be employed.

FIG. 2 is a cross-sectional view of the semiconductor structure of FIG. 1 where litho patterning takes place to form a first set of a plurality of metal trenches, in accordance with an embodiment of the present invention.

In various example embodiments, the bilayer metal is etched to form a set of a plurality of first metal trenches. Some of the first set of the plurality metal trenches 22 have a first width and some of the first set of the plurality of metal trenches 24 have a second width, where the first width is greater than the second width. The etching extends to a top surface of the dielectric material 10. The first set of the plurality of metal trenches 22, 24 have a bilayer metal arrangement.

The etching can include a dry etching process such as, for example, wet etch, reactive ion etching, plasma etching, ion etching or laser ablation. The etching can further include a wet chemical etching process in which one or more chemical etchants are used to remove portions of the blanket layers that are not protected by the patterned photoresist.

The dry and wet etching processes can have etching parameters that can be tuned, such as etchants used, etching temperature, etching solution concentration, etching pressure, source power, RF bias voltage, RF bias power, etchant flow rate, and other suitable parameters. Dry etching processes can include a biased plasma etching process. Ruthenium metal is generally etched using O₂ with Ar for the physical component and CH₄ as a dilution gas to reduce the polymerization. Other dry etchant gasses can include, chlorine base gases (e.g., Cl₂, BCl₃), Tetrafluoromethane (CF₄), nitrogen trifluoride (NF₃), sulfur hexafluoride (SF₆), and helium (He), and Chlorine trifluoride (ClF₃). Dry etching can also be performed anisotropically using such mechanisms as DRIE (deep reactive-ion etching). Chemical vapor etching can be used as a selective etching method, and the etching gas can include hydrogen chloride (HCl), Tetrafluoromethane (CF₄), and gas mixture with hydrogen (H₂). Chemical vapor etching can be performed by CVD with suitable pressure and temperature.

FIG. 3 is a cross-sectional view of the semiconductor structure of FIG. 2 where a cut mask is optionally applied to selectively remove metal trench portions, in accordance with an embodiment of the present invention.

In various example embodiments, a cut mask 26 is applied to selectively remove metal trench portions. The removed metal trench portion is crossed out by an “X.” It is noted that this can be an optional step.

FIG. 4 is a cross-sectional view of the semiconductor structure of FIG. 3 where a first dielectric is deposited and planarization takes place to a top surface of the first set of the plurality of metal trenches, in accordance with an embodiment of the present invention.

In various example embodiments, a first dielectric 28 is deposited and planarization takes place to a top surface of the first set of the plurality of metal trenches 22, 24. The first dielectric 28 can be e.g., an ultra-low-k (ULK) dielectric.

FIG. 5 is a cross-sectional view of the semiconductor structure of FIG. 3 where spacers are formed, a first dielectric is deposited, and planarization takes place to a top surface of the first set of the plurality of metal trenches, in accordance with another embodiment of the present invention.

In various example embodiments, spacers 30, 32 are formed, the first dielectric 28 is deposited, and planarization takes place to a top surface of the first set of the plurality of metal trenches 22, 24. In FIG. 4, in one embodiment, no spacers are formed. In FIG. 5, however, the spacers 30, 32 are formed adjacent the first set of the plurality of metal trenches 22, 24. The spacer 32 illustrates a pinch-off region. The spacer 32 can also be referred to as a pinched off spacer.

The spacers 30, 32 can include any of one or more of TEOS, SiO₂, SiN, SiBN, SiCN and/or SiBCN films.

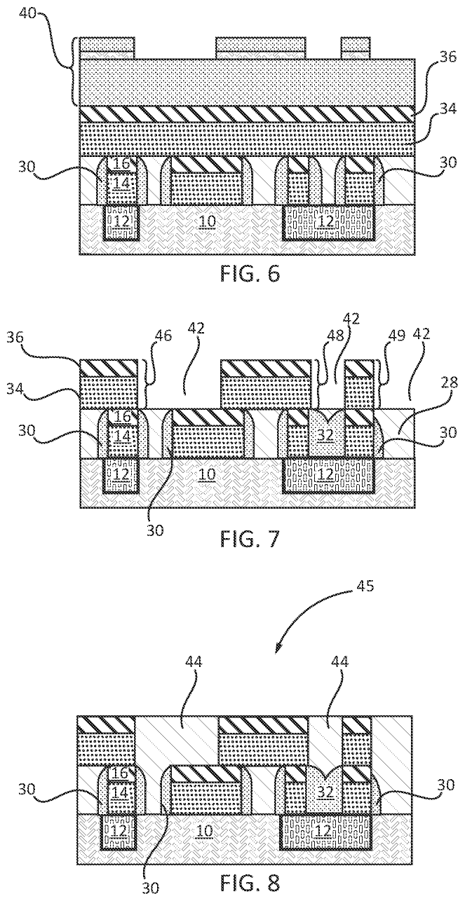

FIG. 6 is a cross-sectional view of the semiconductor structure of FIG. 5 where metal layers and another litho stack are formed thereon, in accordance with an embodiment of the present invention.

In various example embodiments, another bilayer metal is deposited. The second bilayer metal includes a first metal layer 34 and a second metal layer 36. A litho stack 40 is deposited over the first metal layer 34 and the second metal layer 36. The first metal layer 34 can be, e.g., ruthenium (Ru). The Ru layer can have a thickness of about 10 to 50 nm. The second metal layer 36 can be, e.g., titanium nitride (TiN) or tantalum nitride (TaN). The TiN or TaN layer can have a thickness of about 5-10 nm.

FIG. 7 is a cross-sectional view of the semiconductor structure of FIG. 6 where the metal layers are etched to a top surface of the first set of the plurality of metal trenches below to expose the first dielectric and to create a second set of a plurality of metal trenches, in accordance with an embodiment of the present invention.

In various example embodiments, the first and second metal layers 34, 36 are etched to a top surface of the first set of the plurality of metal trenches 22, 24 below to create openings 42 and to expose the first dielectric 28 and to create a second set of a plurality of metal trenches 46, 48, 49.

In various example embodiments, the second bilayer metal is etched to form the second set of a plurality of metal trenches 46, 48, 49. Some of the second set of the plurality of metal trenches 46 have a first width and some of the second set of the plurality of metal trenches 48 have a second width, where the first width is less than the second width. The etching extends to a top surface of the first dielectric 28 and the top of the second metal layer 16 in the exposed area.

The second set of the plurality of metal trenches 46, 48, 49 directly contact the first set of the plurality of metal trenches 22, 24 below. In one example, a top metal trench can contact a portion of a bottom metal trench. In another example, a top metal trench can contact more than one bottom metal trench. In yet another example, a top metal trench can contact an entire upper surface of a bottom metal trench. Different top/bottom metal trenches contact configurations or schemes or patterns can be envisioned by one skilled in the art.

In this figure, a mixture of spacers and a pinched spacer are shown. Some embodiments may include the pinched spacer and some may not depending on desired applications.

FIG. 8 is a cross-sectional view of the semiconductor structure of FIG. 7 where a second dielectric is deposited and planarization takes place to a top surface of the second set of the plurality of metal trenches, in accordance with an embodiment of the present invention.

In various example embodiments, a second dielectric 44 is deposited and planarization takes place to a top surface of the second set of the plurality of metal trenches 46, 48, 49. Structure 45 illustrates a first embodiment of a M2V1 layer formed over an M1 layer by including spacers. The 3D representation of such structure is shown in FIG. 19 below. The first set of the plurality of metal trenches 22, 24 and the second set of the plurality of metal trenches 46, 48, 49 collectively define the M2V1 layer.

Therefore, the structure 45 includes a first level of interconnect wiring and a second level of interconnect wiring having a bilayer metal arrangement incorporating via elements, the second level of interconnect wiring electrically connected to the first level of interconnect wiring. The bilayer metal arrangement of the second level of interconnect wiring includes a first row of bilayer metals and a second row of bilayer metals disposed over the first row of bilayer metals. The second row of bilayer metals directly contacts the first row of bilayer metals. Spacers are formed adjacent the first row of bilayer metals. Moreover, the first level of interconnect wiring has a first pattern and the second level of interconnect wiring has a second pattern, the first and second patterns being different from each other.

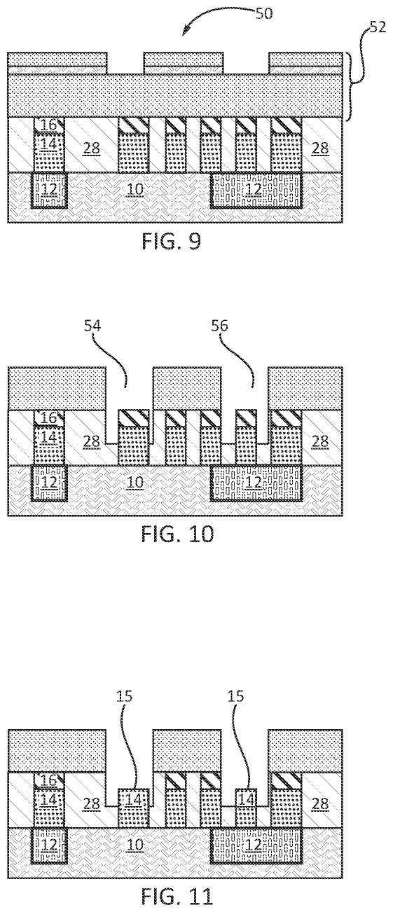

FIG. 9 is a cross-sectional view of the semiconductor structure of FIG. 4 where litho patterning takes place over the first set of the plurality of metal trenches, in accordance with another embodiment of the present invention.

In various example embodiments, in structure 50, litho patterning takes place over the first set of the plurality of metal trenches 22, 24. A litho stack 52 is deposited over the first set of the plurality of metal trenches 22, 24.

FIG. 10 is a cross-sectional view of the semiconductor structure of FIG. 9 where selective etching takes place to expose one or more of the first set of the plurality of metal trenches, in accordance with an embodiment of the present invention.

In various example embodiments, selective etching takes place to expose one or more of the first set of the plurality of metal trenches. The etching results in an opening 54 and an opening 56. The opening 54 exposes a first metal trench and the opening 56 exposes a second metal trench. In one example, the first and second metal trenches can have a different width.

FIG. 11 is a cross-sectional view of the semiconductor structure of FIG. 10 where a top metal layer of the exposed first metal trenches is selectively removed, in accordance with an embodiment of the present invention.

In various example embodiments, a top metal layer of the exposed first metal trench is selectively removed. For example, the top metal layer (the second metal layer 16) is removed to exposed a top surface 15 of the bottom metal layer (the first metal layer 14). Sidewalls of the bottom metal layer can also be exposed.

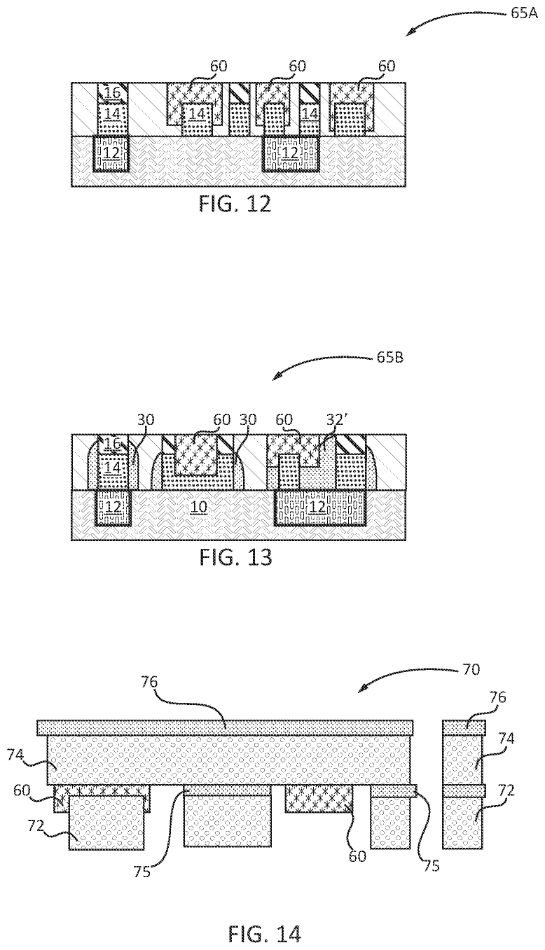

FIG. 12 is a cross-sectional view of the semiconductor structure of FIG. 11 where a cap dielectric material is deposited and planarization is performed, in accordance with an embodiment of the present invention.

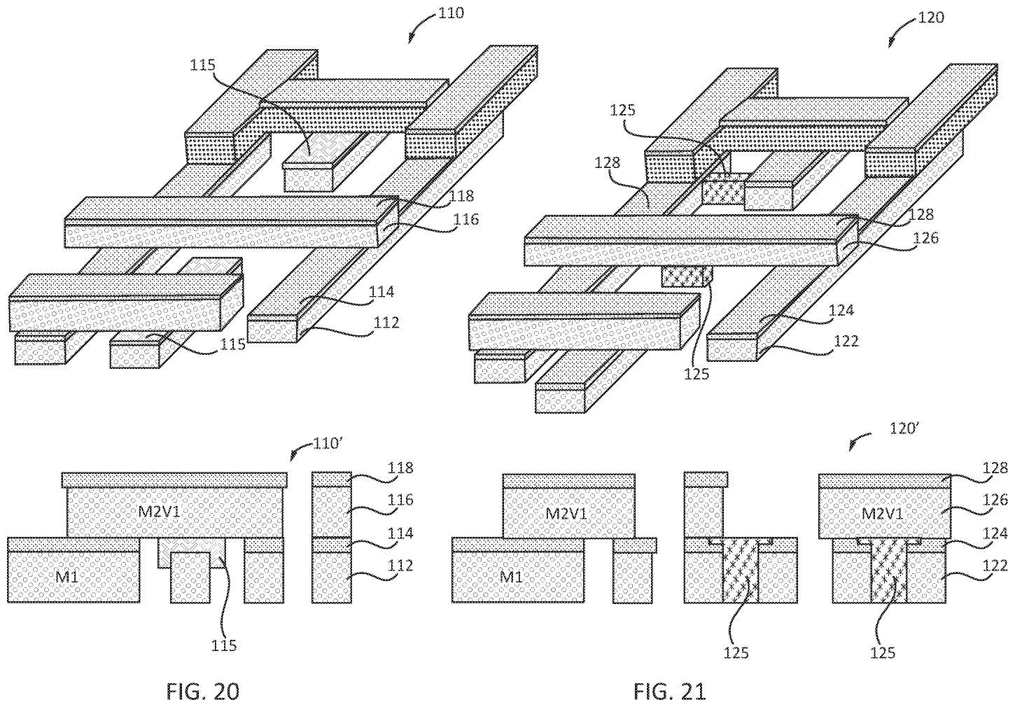

In various example embodiments, a cap dielectric material 60 is deposited and planarization is performed to a top surface of the bilayer metal. Structure 65A illustrates a second embodiment of a M2V1 layer formed over an M1 or MOL contact layer by including the cap dielectric material 60. The 3D representation of such structure is shown in FIG. 20 below. The first set of the plurality of metal trenches 22, 24 and the cap dielectric material 60 collectively define the M2V1 layer. The cap dielectric material 60 is wrapping around the bottom metal layer (or the first metal layer 14).

The cap dielectric material 60 can be, e.g., aluminum oxide (AlOx), aluminum nitride (AlN) or any other dielectric cap material such, e.g., an Nblock, TEOS, SiN, etc.

FIG. 13 is a cross-sectional view of the semiconductor structure of FIG. 5 where a cap dielectric material is deposited and planarization is performed (where spacers are formed adjacent the first set of the plurality of metal trenches), in accordance with an embodiment of the present invention.

In various example embodiments, the cap dielectric material 60 is deposited and planarization is performed where the spacers 30 and the spacers 32′ are formed adjacent the first set of the plurality of metal trenches 22, 24. The cap dielectric material 60 is wrapping around the bottom metal layer (or the first metal layer 14).

Structure 65B illustrates the second embodiment of a M2V1 layer formed over an M1 or MOL contact layer by including the cap dielectric material 60, as well as the spacers 30, 32′ adjacent the first set of the plurality of metal trenches 22, 24. The 3D representation of such structure is shown in FIG. 20 below. The first set of the plurality of metal trenches 22, 24 and the cap dielectric material 60 (with the spacers 30, 32′) collectively define the M2V1 layer.

Therefore, the structure 65A and the structure 65B include a first level of interconnect wiring and a second level of interconnect wiring having a bilayer metal arrangement incorporating via elements and a cap dielectric material, the second level of interconnect wiring electrically connected to the first level of interconnect wiring. In some instances, the cap dielectric material directly contacts only a first metal layer of the bilayer metal arrangement. In other instances, the cap dielectric material directly contacts both a first metal layer and a second metal layer of the bilayer metal arrangement. In structure 65B, spacers are formed adjacent a first metal layer and a second metal layer of the bilayer metal arrangement. The first level of interconnect wiring has a first pattern and the second level of interconnect wiring has a second pattern, the first and second patterns being different from each other.

FIG. 14 is a cross-sectional view of the semiconductor structure of FIGS. 12 and 13 illustrating the cap dielectric material between the M1 layer and the M2V1 layer, in accordance with an embodiment of the present invention.

In various example embodiments, in structure 70, the cap dielectric material 60 is depicted between the M1 layer 72 and the M2V1 layer 74. A top metal 75 and a top metal 76 are also illustrated with respect to the M1 layer 72 and the M2V1 layer 74.

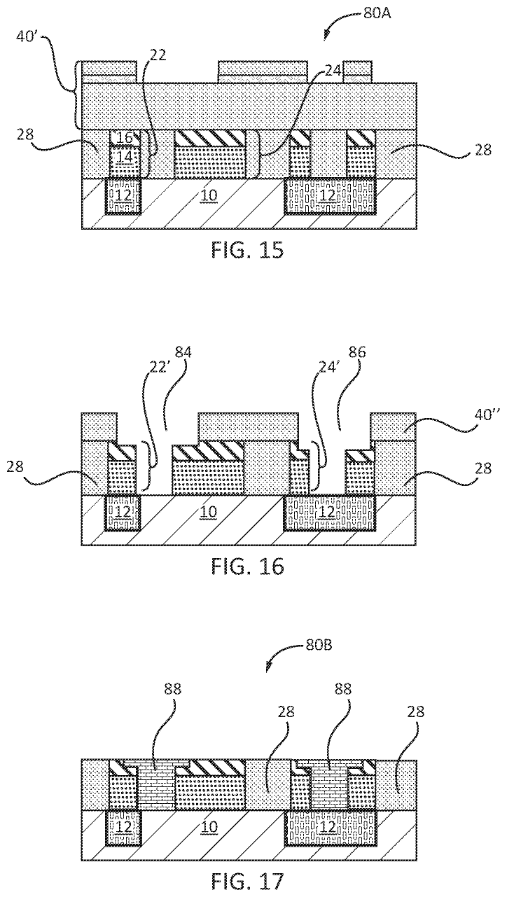

FIG. 15 is a cross-sectional view of the semiconductor structure of FIG. 5 where litho patterning takes place over the first set of the plurality of metal trenches, and where a single dielectric encompasses the first set of the plurality of metal trenches, in accordance with another embodiment of the present invention.

In various example embodiments, in structure 80A, a trilayer stack 40′ is formed over the first set of the plurality of metal trenches 22, 24 and the first dielectric 28.

FIG. 16 is a cross-sectional view of the semiconductor structure of FIG. 15 where selective etching takes place to expose the first set of the plurality of metal trenches, in accordance with another embodiment of the present invention.

In various example embodiments, portions of the trilayer stack 40′ are etched away (resulting in sections 40″) such that the second metal layer 16 maintains the CD within the bilayer metal line. In case the etch selectivity is not good enough, the second metal layer 16 may start to be partially etched away, thus creating a gauge. As a result, the gauged first set of the plurality of metal trenches are designated as 22′, 24′.

FIG. 17 is a cross-sectional view of the semiconductor structure of FIG. 16 where a metal bridge is formed and planarized, in accordance with an embodiment of the present invention.

In various example embodiments, the remaining portions of the trilayer stack 40′ are etched away, and a metal bridge 88 is formed and planarized. The metal bridge 88 is formed between the metal trenches. The metal bridge 88 provides for a connection between the bilayer metals. The metal bridge 88 could be non-limiting examples of suitable conductive materials like, e.g., molybdenum, iridium, tungsten, titanium, tantalum, ruthenium, zirconium, cobalt, copper, aluminum, lead, platinum, tin, silver, gold), or any suitable combination of these materials.

Structure 80B illustrates the third embodiment of a M2V1 layer formed over an M1 or MOL contact layer by including the metal bridge 88. The 3D representation of such structure is shown in FIG. 21 below. The gauged first set of the plurality of metal trenches 22′, 24′ and the metal bridge 88 collectively define the M2V1 layer. The metal bridge 88 can thus define a substantially or generally T-shaped configuration as a result of the gauged first set of the plurality of metal trenches of FIG. 16.

Therefore, the structure 80B includes a first level of interconnect wiring and a second level of interconnect wiring having a bilayer metal arrangement incorporating via elements and a metal bridge, the second level of interconnect wiring electrically connected to the first level of interconnect wiring. The metal bridge directly contacts the bilayer metal arrangement. The metal bridge extends from the first level of interconnect wiring to the second level of interconnect wiring. The first level of interconnect wiring has a first pattern and the second level of interconnect wiring has a second pattern, the first and second patterns being different from each other.

In an alternative embodiment, the metal bridge 88 and the cap dielectric material 60 can be combined into a single structure including the M2V1 layer formed over the M1 or MOL contact layer.

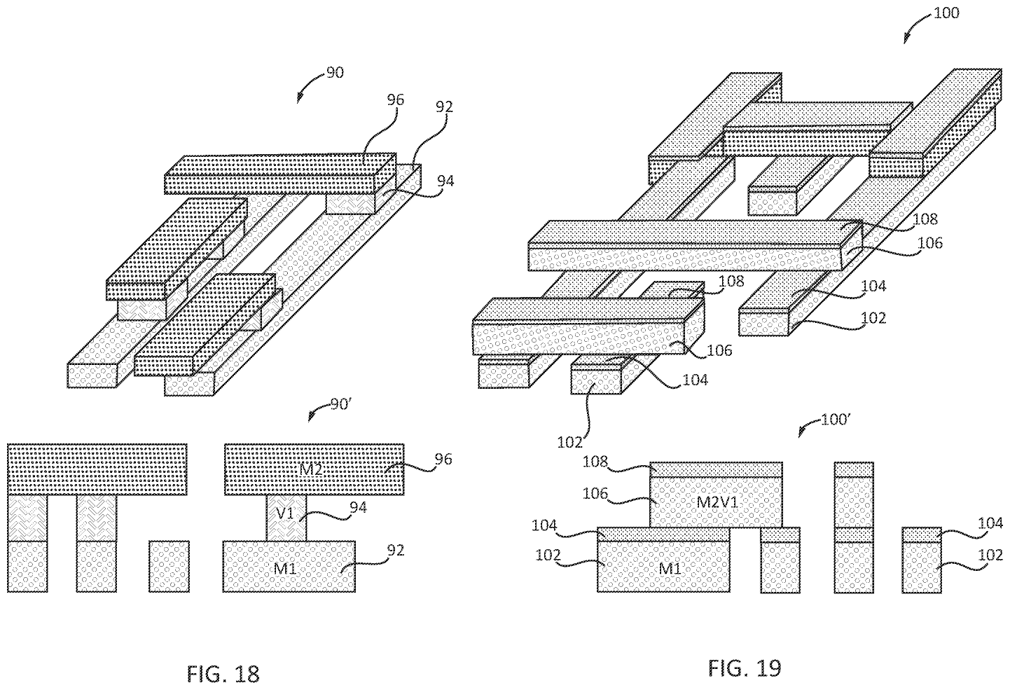

FIG. 18 is a 3D view and cross-sectional view of a via (V1) connecting an M1 layer to an M2 layer.

In a conventional system, vias are employed to connect multiple metal layers. For example, via 94 (V1) connects the M1 layer 92 to the M2 layer 96. Structure 90 illustrates a 3D representation and structure 90′ illustrates a cross-sectional representation. It is noted that the empty space is filled with a dielectric (not shown).

FIG. 19 is a 3D view and cross-sectional view of a M2V1 layer connected over an M1 layer composed by a bi-metal as illustrated in FIG. 8, in accordance with an embodiment of the present invention.

In various example embodiments, the via element is combined with the metal elements. For example, structure 100 illustrates a 3D representation where an M1 bilayer layer 102 and 104 is connected to a M2V1 bi-layer metal 106 and 108. Structure 100′ illustrates the cross-sectional view depicting the M1 bilayer 102 and 104 connected to the M2V1 bilayer 106 and 108. It is noted that the empty space is filled with a dielectric (not shown).

FIG. 20 is a 3D view and cross-sectional view of a M2V1 layer connected to an M1 layer and isolated by a cap dielectric material in selected region as illustrated in FIG. 13, in accordance with an embodiment of the present invention.

The M2V1 layer connected over the M1 layer is composed of a bilayer metal 112 and 114, and isolated from M1 by a cap dielectric material 115.

In various example embodiments, the via element is combined with the metal elements. For example, structure 110 illustrates a 3D representation where the M1 layer with the bilayer metal 112/114 is connected to the M2V1 layer 116 and 118. The M1 layer is isolated from the M2V1 layer 116 and 118 by the cap dielectric material 115. The cap dielectric material 115 is wrapping around M1 layer for achieving better isolation.

FIG. 21 is a 3D view and cross-sectional view of a M2V1 layer connected to an M1 layer by a bridge metal as illustrated in FIG. 17, in accordance with an embodiment of the present invention.

In various example embodiments, the via element is combined with the metal elements. For example, structure 120 illustrates a 3D representation where an M1 layer with the bilayer metal 112/114 is connected to the M2V1 layer 126/128 and a metal bridge 125. Structure 120′ illustrates the cross-sectional view depicting the M1 layer with the bilayer metal 112/114 connected to the M2V1 layer 126/128 and the metal bridge 125. The metal bridge 125 extends from the M1 layer with the bilayer metal 112/114 to the M2V1 layer 126/128. The metal bridge 125 can have a substantially or generally T-shaped configuration.

In semiconductor design technology, many metal layers are employed to implement interconnections throughout an integrated circuit. For some integrated circuits, one or more polysilicon (poly) layers, or even active areas, are also used to implement interconnections. Vias are employed to connect from one such metal or polysilicon layer to another metal or polysilicon layer. For example, a via can be used to connect a feature (e.g., a design geometry) on each of two metal layers. The lower one of the two layers is referred to as the landing metal layer and the upper one of the two layers is referred to as the covering layer. A via between a landing metal layer mtₓ and the covering metal layer mtₓ₊₁ is usually referred to as a vₓ via (e.g., using the same subscript designation as the landing metal layer). Embodiments in accordance with the present invention provide methods and devices for combining the vias into the metal layer thus constructing a multi single-level scheme combining trench and via elements. The pattern can be achieved by employing self-aligned double patterning (SADP) or self-aligned litho-etch-litho-etch (SALELE) or litho-etch-litho-etch (LELE) with a cut.

In conclusion, the exemplary embodiments of the present invention introduce metal via multi-levels. The exemplary semiconductor structures include multi single-level schemes combining trench and via elements. The pattern can be achieved by employing single exposition patterning (SE), self-aligned double patterning (SADP) or self-aligned litho-etch-litho-etch (SALELE) or litho-etch-litho-etch (LELE) with a cut. As a result, there is no need of a specific via mask with a feature like a self-aligned via (SA V) or fully self-aligned via (FSAV). This results in an overlay improvement as a line-over-line configuration is achieved and a reduced footprint as via-to-via distance doesn't exist.

Regarding FIGS. 1-21, deposition is any process that grows, coats, or otherwise transfers a material onto the wafer. Available technologies include, but are not limited to, thermal oxidation, physical vapor deposition (PVD), chemical vapor deposition (CVD), electrochemical deposition (ECD), molecular beam epitaxy (MBE) and more recently, atomic layer deposition (ALD) among others. As used herein, “depositing” can include any now known or later developed techniques appropriate for the material to be deposited including but not limited to, for example: chemical vapor deposition (CVD), low-pressure CVD (LPCVD), plasma-enhanced CVD (PECVD), semi-atmosphere CVD (SACVD) and high density plasma CVD (HDPCVD), rapid thermal CVD (RTCVD), ultra-high vacuum CVD (UHVCVD), limited reaction processing CVD (LRPCVD), metal-organic CVD (MOCVD), sputtering deposition, ion beam deposition, electron beam deposition, laser assisted deposition, thermal oxidation, thermal nitridation, spin-on methods, physical vapor deposition (PVD), atomic layer deposition (ALD), chemical oxidation, molecular beam epitaxy (MBE), plating, evaporation.

The term “processing” as used herein includes deposition of material or photoresist, patterning, exposure, development, etching, cleaning, stripping, implanting, doping, stressing, layering, and/or removal of the material or photoresist as needed in forming a described structure.

Removal is any process that removes material from the wafer: examples include etch processes (either wet or dry), and chemical-mechanical planarization (CMP), etc.

Patterning is the shaping or altering of deposited materials, and is generally referred to as lithography. For example, in conventional lithography, the wafer is coated with a chemical called a photoresist; then, a machine called a stepper focuses, aligns, and moves a mask, exposing select portions of the wafer below to short wavelength light; the exposed regions are washed away by a developer solution. After etching or other processing, the remaining photoresist is removed. Patterning also includes electron-beam lithography and EUV techniques.

Non-limiting examples of suitable conductive materials include doped polycrystalline or amorphous silicon, germanium, silicon germanium, a metal (e.g., molybdenum, iridium, tungsten, titanium, tantalum, ruthenium, zirconium, cobalt, copper, aluminum, lead, platinum, tin, silver, gold), a conducting metallic compound material (e.g., tantalum nitride, titanium nitride, tantalum carbide, titanium carbide, titanium aluminum carbide, tungsten silicide, tungsten nitride, ruthenium oxide, cobalt silicide, nickel silicide), carbon nanotube, conductive carbon, graphene, or any suitable combination of these materials. The conductive material can further comprise dopants that are incorporated during or after deposition. The conductive material can be deposited by a suitable deposition process, for example, CVD, PECVD, PVD, plating, thermal or e-beam evaporation, and sputtering.

It is to be understood that the present invention will be described in terms of a given illustrative architecture; however, other architectures, structures, substrate materials and process features and steps/blocks can be varied within the scope of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical mechanisms (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which usually include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present embodiments. The compounds with additional elements will be referred to herein as alloys.

Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of methods and structures providing for constructing metal via multi-levels (which are intended to be illustrative and not limiting), it is noted that modifications and variations can be made by persons skilled in the art in light of the above teachings. It is therefore to be understood that changes may be made in the particular embodiments described which are within the scope of the invention as outlined by the appended claims. Having thus described aspects of the invention, with the details and particularity required by the patent laws, what is claimed and desired protected by Letters Patent is set forth in the appended claims.

1. A semiconductor structure comprising:
a first level of interconnect wiring; and
a second level of interconnect wiring having a bilayer metal arrangement incorporating via elements, the second level of interconnect wiring electrically connected to the first level of interconnect wiring.

2. The semiconductor structure of claim 1, wherein the bilayer metal arrangement of the second level of interconnect wiring includes a first row of bilayer metals and a second row of bilayer metals disposed over the first row of bilayer metals.

3. The semiconductor structure of claim 2, wherein the second row of bilayer metals directly contacts the first row of bilayer metals.

4. The semiconductor structure of claim 2, wherein spacers are formed adjacent the first row of bilayer metals.

5. The semiconductor structure of claim 2, wherein a first metal layer of the first and second rows of bilayer metals includes ruthenium (Ru).

6. The semiconductor structure of claim 5, wherein a second metal layer of the first and second rows of bilayer metals includes tantalum nitride (TaN) or titanium nitride (TiN).

7. The semiconductor structure of claim 1, wherein the first level of interconnect wiring has a first pattern and the second level of interconnect wiring has a second pattern, the first and second patterns being different from each other.

8. A semiconductor structure comprising:
a first level of interconnect wiring; and
a second level of interconnect wiring having a bilayer metal arrangement incorporating via elements and a cap dielectric material, the second level of interconnect wiring electrically connected to the first level of interconnect wiring.

9. The semiconductor structure of claim 8, wherein the cap dielectric material isolates a first bilayer metal from a second bilayer metal.

10. The semiconductor structure of claim 8, wherein the second level of interconnect wiring further includes a metal bridge.

11. The semiconductor structure of claim 8, wherein spacers are formed adjacent a first metal layer and a second metal layer of the bilayer metal arrangement.

12. The semiconductor structure of claim 11, wherein the first metal layer of the bilayer metal arrangement includes ruthenium (Ru).

13. The semiconductor structure of claim 12, wherein the second metal layer of the bilayer metal arrangement includes tantalum nitride (TaN) or titanium nitride (TiN).

14. The semiconductor structure of claim 8, wherein the first level of interconnect wiring has a first pattern and the second level of interconnect wiring has a second pattern, the first and second patterns being different from each other.

15. A semiconductor structure comprising:
a first level of interconnect wiring; and
a second level of interconnect wiring having a bilayer metal arrangement incorporating via elements and a metal bridge, the second level of interconnect wiring electrically connected to the first level of interconnect wiring.

16. The semiconductor structure of claim 15, wherein the metal bridge directly contacts the bilayer metal arrangement.

17. The semiconductor structure of claim 15, wherein a first metal layer of the bilayer metal arrangement includes ruthenium (Ru).

18. The semiconductor structure of claim 17, wherein a second metal layer of the bilayer metal arrangement includes tantalum nitride (TaN) or titanium nitride (TiN).

19. The semiconductor structure of claim 15, wherein the first level of interconnect wiring has a first pattern and the second level of interconnect wiring has a second pattern, the first and second patterns being different from each other.

20. The semiconductor structure of claim 15, wherein the metal bridge extends from the first level of interconnect wiring to the second level of interconnect wiring.
